(19) United States
(12) Patent Application Publication
(10) Pub. No.: US 2026/0293170 A1
(43) Pub. Date: Sep. 24, 2026

(54) SEMICONDUCTOR DEVICE STRUCTURE AND METHOD FOR FORMING THE SAME

(71) Applicant: TAIWAN SEMICONDUCTOR MANUFACTURING COMPANY LTD., HSINCHU (TW)

(72) Inventors: CHENG-HAO CHIU, CHANGHUA COUNTY (TW); CHIA-YU WEI, TAINAN CITY (TW); KUO-CHENG LEE, TAINAN CITY (TW); WEN-CHUNG CHEN, HSINCHU (TW); TZU-WEI WANG, HSINCHU (TW); KUAN-TING SONG, KAOHSIUNG CITY (TW); HSUN-YING HUANG, TAINAN CITY (TW)

(21) Appl. No.: 19/086,183

(22) Filed: Mar. 21, 2025

(51) Int. Cl. H10D 1/68; H10F 39/00

(52) U.S. Cl. CPC H10D 1/696; H10F 39/014; H10F 39/804; H10F 39/811; H10F 39/807

(57) ABSTRACT

A semiconductor device structure and a method for forming a semiconductor device structure are provided. The method includes following operations: forming a first conductive layer over a semiconductor substrate; forming a dielectric layer over the first conductive layer; forming a second conductive layer over the dielectric layer; forming a dielectric structure encapsulating the first conductive layer, the dielectric layer, and the second conductive layer; and forming a reinforcing layer between the first conductive layer and a portion of the dielectric structure, wherein a Young's modulus of the reinforcing layer is greater than a Young's modulus of the first conductive layer.

### BACKGROUND

Semiconductor image sensors are used to sense radiation, such as light. Complementary metal-oxide-semiconductor (CMOS) image sensors (CIS) are widely used in various applications, such as digital cameras and mobile phone cameras. Such cameras utilize an array of pixels located in a substrate, including photodiodes and transistors that can absorb radiation projected toward the substrate and convert the sensed radiation into electrical signals.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1A is a cross-section of a semiconductor device structure according to one or more embodiments of the present disclosure.

FIG. 1B is a cross-section of a semiconductor device structure according to one or more embodiments of the present disclosure.

FIG. 2A is a cross-section of a capacitor structure according to one or more embodiments of the present disclosure.

FIG. 2B is a cross-section of a capacitor structure according to one or more embodiments of the present disclosure.

FIG. 2C is a cross-section of a capacitor structure according to one or more embodiments of the present disclosure.

FIG. 2D is a cross-section of a capacitor structure according to one or more embodiments of the present disclosure.

FIG. 2E is a cross-section of a capacitor structure according to one or more embodiments of the present disclosure.

FIG. 2F is a cross-section of a capacitor structure according to one or more embodiments of the present disclosure.

FIG. 2G is a cross-section of a capacitor structure according to one or more embodiments of the present disclosure.

FIG. 2H is a cross-section of a capacitor structure according to one or more embodiments of the present disclosure.

FIG. 3A is a perspective view of a capacitor structure according to one or more embodiments of the present disclosure.

FIG. 3B is a perspective view of a capacitor structure according to one or more embodiments of the present disclosure.

FIG. 3C is a perspective view of a capacitor structure according to one or more embodiments of the present disclosure.

FIG. 3D is a perspective view of a capacitor structure according to one or more embodiments of the present disclosure.

FIGS. 4A to 4H are cross-sections illustrating a method for forming a capacitor structure according to one or more embodiments of the present disclosure.

FIGS. 5A to 5D are cross-sections illustrating a method for forming a capacitor structure according to one or more embodiments of the present disclosure.

FIGS. 6A to 6D are cross-sections illustrating a method for forming a capacitor structure according to one or more embodiments of the present disclosure.

FIGS. 7A to 7B are cross-sections illustrating a method for forming a capacitor structure according to one or more embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” or “about” generally mean within a value or range that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

Embodiments of the present disclosure discuss a semiconductor device package including one or more reinforcing layers are disposed between a capacitor structure and at least a portion a dielectric structure encapsulating the capacitor structure, and the reinforcing layer further contacts the dielectric structure. Therefore, the structural strength of the semiconductor device package (e.g., the image sensor structure) is increased, warpage is reduced, and number of white pixels can be significantly reduced.

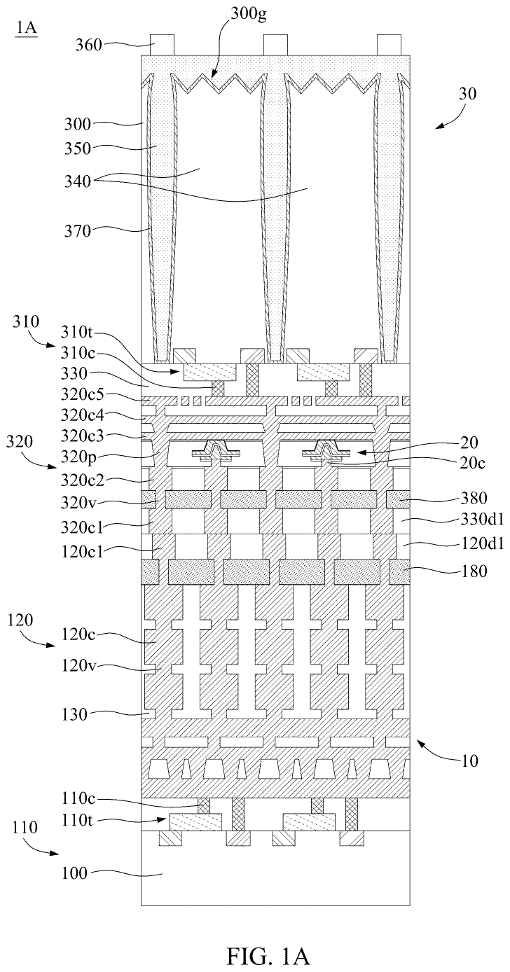

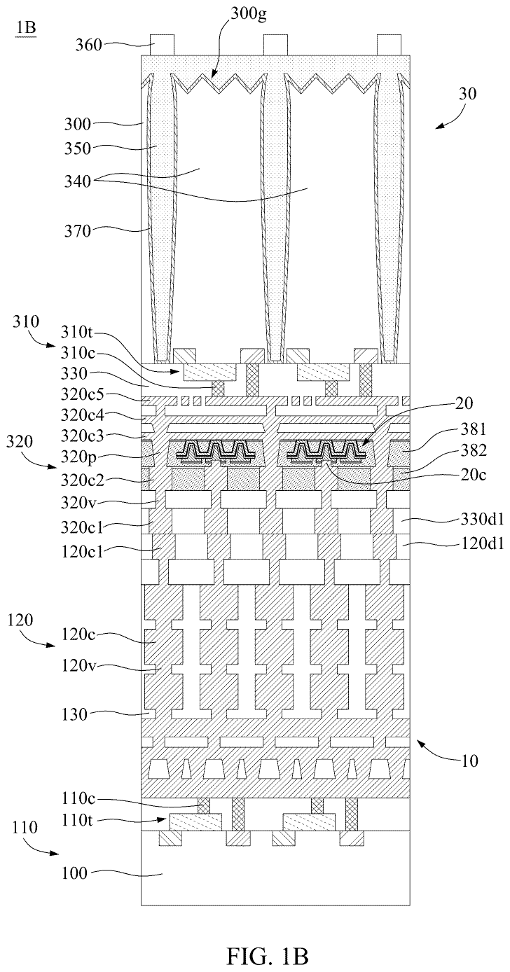

FIG. 1A is a cross-section of a semiconductor device structure 1A according to one or more embodiments of the present disclosure. The semiconductor device structure 1A may include dies 10 and 30. The dies 10 and 30 may be referred to as semiconductor structures or semiconductor devices. The semiconductor device structure 1A may be referred to as an image sensor structure.

The die 10 may include a semiconductor substrate 100, a circuit layer 110, a redistribution layer (RDL) 120, and a dielectric structure 130. The die 10 may be or include an ASIC. The die 10 may further include a reinforcing layer 180.

The semiconductor substrate 100 may be or include silicon (Si), germanium (Ge), and/or compound semiconductor materials such as gallium arsenide (GaAs), but the present disclosure is not limited thereto.

The circuit layer 110 may be disposed over or partially in the semiconductor substrate 100. In some embodiments, the circuit layer 110 includes transistors 110t and connection elements 110c (e.g., conductive vias, conductive pads, conductive pillars or the like) electrically connecting the transistors 110t to the RDL 120. The circuit layer 110 may be or include a logic circuitry, e.g., an image-signal processor.

The RDL 120 may be disposed over the circuit layer 110. In some embodiments, the RDL 120 includes conductive layers 120c and 120c1 and connection elements 120v (e.g., conductive vias, conductive pads, conductive pillars or the like) electrically connected to the conductive layers 120c and 120c1. The conductive layers 120c and 120c1 may be referred to as interconnect layers. The conductive layer 120c1 may be referred to as a topmost conductive layer 120c1 that electrically connects to the die 30.

The dielectric structure 130 may encapsulate the circuit layer 110 and the RDL 120. The dielectric structure 130 may include a plurality of dielectric layers. The plurality of dielectric layers may be formed of or include the same or different dielectric materials.

The die 30 may be stacked over the die 10. In some embodiments, the die 30 is bonded to or connected to the die 10. The die 30 may include a semiconductor substrate 300, a circuit layer 310, a RDL 320, a dielectric structure 330, image sensing elements 340, isolation structures 350, a grid structure 360, and a dielectric liner 370. The die 30 may be or include a system-on-chip (SoC). The die 30 may further include a capacitor structure 20. The die 30 may further include a reinforcing layer 380. There may be an alignment shift between the dies 10 and 30.

The semiconductor substrate 300 may be a p-type substrate. For example, the semiconductor substrate 300 may be or include a silicon substrate doped with a p-type dopant such as boron. Alternatively, the semiconductor substrate 300 may be an n-type substrate. For example, the semiconductor substrate 300 may be or include a silicon substrate doped with an n-type dopant such as phosphorous or arsenic. The semiconductor substrate 300 may include other elementary semiconductor materials such as germanium. In some embodiments, the semiconductor substrate 300 has a plurality of grooves 300g extending toward the image sensing elements 340. In some embodiments, the grooves 300g form a periodic groove pattern and located at pixel regions (e.g., the image sensing elements 340). The grooves 300g may alter the surface topography of the pixel regions of the semiconductor substrate 300, such that an additional surface area of the pixel regions may be exposed, as compared to a planar surface of the semiconductor substrate 300. In some embodiments, the grooves 300g are configured to provide an increase in exposed areas per horizontal unit area that can be achieved without adjusting the areas of the pixel regions. Increasing the exposed surface area increases the effective light incident area and in turn increases the incident light intensity received by the pixel regions (e.g., the image sensing elements 340). As a result, the quantum efficiency of the pixels is improved.

The circuit layer 310 may be formed over or partially in the semiconductor substrate 300 and within the pixel regions. In some embodiments, the circuit layer 310 includes transistors 310t and connection elements 310c (e.g., conductive vias, conductive pads, conductive pillars or the like) electrically connecting the transistors 310t to the RDL 320. In some embodiments, the transistors 310t may include a transfer transistor, a source-follower transistor, a row select transistor, a reset transistor, or any combination thereof. In some embodiments, the transistors 310t are electrically connected with the image sensing elements 340 to collect (or pick up) electrons generated by incident light (or incident radiation) traveling into the image sensing elements 340 and to convert the electrons into voltage signals.

The RDL 320 may be disposed over the circuit layer 310. In some embodiments, the RDL 320 includes conductive layers 320c1, 320c2, 320c3, 320c4, and 320c5 and connection elements 320v and 320p (e.g., conductive vias, conductive pads, conductive pillars or the like) electrically connecting the conductive layers 320c1, 320c2, 320c3, 320c4, and 320c5. The conductive layers 320c1, 320c2, 320c3, 320c4, and 320c5 may be referred to as interconnect layers. The conductive layer 320c1 may be referred to as a bottommost conductive layer that may be electrically connected to or contact the conductive layer 120c1 (or the topmost conductive layer 120c1). The RDL 320 may be misaligned with the RDL 120. In some embodiments, the conductive layer 320c1 is misaligned with the conductive layer 120c1.

The dielectric structure 330 may encapsulate the circuit layer 310 and the RDL 320. The dielectric structure 330 may further encapsulate the capacitor structure 20. The dielectric structure 330 may include a plurality of dielectric layers. The plurality of dielectric layers may be formed of or include the same or different dielectric materials. The dielectric structure 330 may be connected to or contact the dielectric structure 130.

The image sensing elements 340 may be over the semiconductor substrate 100. In some embodiments, the image sensing elements 340 are in the semiconductor substrate 300. In some embodiments, pixel regions may include pixels each with an image sensing element 340. In some embodiments, the image sensing elements 340 may be or include photodetectors, such as photodiodes. In some embodiments, the image sensing elements 340 may be or include doped regions doped with dopants having a doping polarity opposite from that of the semiconductor substrate 300. The image sensing elements 340 may be formed by one or more implantation processes or diffusion processes. The image sensing elements 340 are operable to sense incident light (or incident radiation) that enters the pixel region. The incident light may be visible light. In some embodiments, the incident light may be infrared (IR), ultraviolet (UV), X-ray, microwave, other suitable types of light, or a combination thereof.

The isolation structures 350 may be between the image sensing elements 340 and configured to reflect an incident light received by the semiconductor device structure 1A (or the image sensor structure). In some embodiments, the isolation structures 350 may be or include a deep trench reflective isolation structure.

The grid structure 360 may be over the semiconductor substrate 100. In some embodiments, the grid structure 360 is over the image sensing elements 340 and the isolation structures 350. In some embodiments, the grid structure 360 is aligned with the isolation structures 350. In some embodiments, a width of the grid structure 360 is less than a width of the isolation structures 350. The grid structure 360 may be used to prevent the incident light from entering a neighboring pixel, and thus the crosstalk problems between pixels can be reduced or prevented. In some embodiments, the grid structure 360 is made of or includes a metal material, such as a reflective metal. In some embodiments, the grid structure 360 is made of or includes aluminum, silver, copper, titanium, platinum, tungsten, tantalum, tantalum nitride, other suitable materials, or a combination thereof.

The dielectric liner 370 may be between the image sensing elements 340. The dielectric liner 370 may include silicon oxides or other suitable insulating materials. In some embodiments, the dielectric liner 370 may be or include a high-k dielectric structure. In some embodiments, the dielectric liner 370 includes hafnium oxide (HfO₂), tantalum pentoxide (Ta₂O₅), zirconium dioxide (ZrO₂), aluminum oxide (Al₂O₃), other high-k material, and/or combinations thereof. In some embodiments, the dielectric liner 370 is configured to passivate inner surfaces (or inner walls) of the isolation structures 350. In some embodiments, the dielectric liner 370 is configured to electrically isolate the image sensing elements 340 from one another to reduce electrical crosstalk between the image sensing elements 340.

The capacitor structure 20 may be between the semiconductor substrate 100 and the image sensing elements 340. In some embodiments, the capacitor structure 20 is disposed between and electrically connected to the conductive layers 320c2 and 320c3 of the RDL 320. In some embodiments, the capacitor structure 20 includes a plurality of capacitor portions each disposed corresponding to each of the pixel regions (e.g., the image sensing elements 340). In some embodiments, the capacitor portions of the capacitor structure are disposed under openings defined by the isolation structures 350. In some embodiments, the capacitor structure 20 includes 3D metal-insulator-metal (MIM) capacitors.

The reinforcing layer 180 may be referred to as a stress-resistant layer. In some embodiments, the reinforcing layer 180 is between the capacitor structure 20 and a portion the dielectric structure 130, and the reinforcing layer 180 contacts the dielectric structure 130. In some embodiments, the reinforcing layer 180 is embedded in the dielectric structure 130 and contacts at least one of the interconnect layers of the RDL 120. In some embodiments, the reinforcing layer 180 contacts the conductive layers 120c and 120c1 and the connection elements 120v.

In some embodiments, a Young's modulus of the reinforcing layer 180 is greater than a Young's modulus of the RDL 120. In some embodiments, a Young's modulus of the reinforcing layer 180 is greater than a Young's modulus of the dielectric structure 130. In some embodiments, the Young's modulus of the reinforcing layer 180 is equal to or greater than about 200 GPa, e.g., from about 200 GPa to about 1200 GPa. In some embodiments, the Young's modulus of the reinforcing layer 180 is equal to or greater than about 300 GPa, 400 GPa, 500 GPa, 600 GPa, 700 GPa, 800 GPa, 900 GPa, or 100 GPa. In some embodiments, the reinforcing layer 180 includes Al₂O₃, SiC, Si₃N₄, TiO₂, diamond, or other suitable insulating high modulus materials.

The reinforcing layer 380 may be referred to as a stress-resistant layer. In some embodiments, the reinforcing layer 380 is between the capacitor structure 20 and a portion the dielectric structure 330, and the reinforcing layer 380 contacts the dielectric structure 330. In some embodiments, the reinforcing layer 380 is embedded in the dielectric structure 330 and contacts at least one of the interconnect layers of the RDL 320. In some embodiments, the reinforcing layer 380 contacts the conductive layers 320c1 and 320c2 and the connection elements 320v.

In some embodiments, a Young's modulus of the reinforcing layer 380 is greater than a Young's modulus of the RDL 320. In some embodiments, a Young's modulus of the reinforcing layer 380 is greater than a Young's modulus of the dielectric structure 330. In some embodiments, the Young's modulus of the reinforcing layer 380 is equal to or greater than about 200 GPa, e.g., from about 200 GPa to about 1200 GPa. In some embodiments, the Young's modulus of the reinforcing layer 380 is equal to or greater than about 300 GPa, 400 GPa, 500 GPa, 600 GPa, 700 GPa, 800 GPa, 900 GPa, or 100 GPa. In some embodiments, the reinforcing layer 380 includes Al₂O₃, SiC, Si₃N₄, TiO₂, diamond, or other suitable insulating high modulus materials.

When the number of pixels of a device is increased, the area of each of the pixels may be relatively small, such that the light receiving area may be relatively small. In order to solve the above issues, 3D MIM capacitors may be adopted for increasing capacitance so as to increase resolution of the image sensor device. However, 3D MIM capacitors may exert significant pressure or stress on the semiconductor structure of the device, making the semiconductor structure of the device prone to warpage, which can result in the occurrence of white pixels. In contrast, according to some embodiments of the present disclosure, one or more reinforcing layers are disposed between the capacitor structure and at least a portion the dielectric structure and further contacting the dielectric structure. Therefore, the structural strength of the semiconductor device package (e.g., the image sensor structure) is increased, warpage is reduced, and number of white pixels can be significantly reduced.

In addition, according to some embodiments of the present disclosure, the reinforcing layers having a relatively high Young's modulus contact the dielectric structures and the RDLs of the semiconductor device package. Therefore, the rigidity of the composite structure including the reinforcing layers, the dielectric structures, and the RDLs is increased, thereby enhancing its ability to withstand the stress of 3D MIM capacitors. As a result, warpage of the semiconductor device package can be reduced.

Moreover, according to some embodiments of the present disclosure, the reinforcing layers contact the interconnect layers and are free of conductive materials. Therefore, the reinforcing layers can enhance the structural strength of the semiconductor device package, and undesired short circuit can be prevented.

FIG. 1B is a cross-section of a semiconductor device structure 1B according to one or more embodiments of the present disclosure. The semiconductor device structure 1B may be referred to as an image sensor structure. The semiconductor device structure 1B is similar to the semiconductor device structure 1A in many aspects, and thus descriptions of these aspects are not repeated for brevity.

In some embodiments, the semiconductor device structure 1B includes reinforcing layers 381 and 382. In some embodiments, the RDL 320 includes interconnect layers (e.g., the conductive layers 320c1 to 320c5) at different elevations, and the reinforcing layers 381 and 382 and the capacitor structure 20 are between a first interconnect layer (e.g., the conductive layer 320c2) and a second interconnect layer (e.g., the conductive layer 320c3). In some embodiments, the reinforcing layer 381 is conformally over an outer edge of the capacitor structure 20. In some embodiments, the reinforcing layer 381 contacts the conductive layers 320c2 and 320c3 and the connection element 320p. In some embodiments, the reinforcing layer 382 contacts the conductive layer 302c2. In some embodiments, the reinforcing layers 381 and 382 are spaced apart from each other by a dielectric layer.

In some embodiments, a Young's modulus of each of the reinforcing layers 381 and 382 is greater than a Young's modulus of the RDL 320. In some embodiments, a Young's modulus of each of the reinforcing layers 381 and 382 is greater than a Young's modulus of the dielectric structure 330. In some embodiments, the Young's modulus of each of the reinforcing layers 381 and 382 is equal to or greater than about 200 GPa, e.g., from about 200 GPa to about 1200 GPa. In some embodiments, the Young's modulus of each of the reinforcing layers 381 and 382 is equal to or greater than about 300 GPa, 400 GPa, 500 GPa, 600 GPa, 700 GPa, 800 GPa, 900 GPa, or 100 GPa. In some embodiments, each of the reinforcing layers 381 and 382 includes Al₂O₃, SiC, Si₃N₄, TiO₂, diamond, or other suitable insulating high modulus materials.

According to some embodiments of the present disclosure, the reinforcing layer is conformally over an outer edge of the capacitor structure and contacting the dielectric structure. Therefore, the rigidity of the composite structure including the reinforcing layers, the dielectric structure, and the RDL is increased, thereby enhancing its ability to withstand the stress of 3D MIM capacitors. As a result, warpage of the semiconductor device package can be reduced, and number of white pixels can be significantly reduced.

In addition, according to some embodiments of the present disclosure, the reinforcing layers contact the high-k dielectric layer of the capacitor structure and are free of dielectric materials. Therefore, the reinforcing layers can enhance the structural strength of the semiconductor device package, and the performance of the capacitor structure can be prevented from being adversely affected.

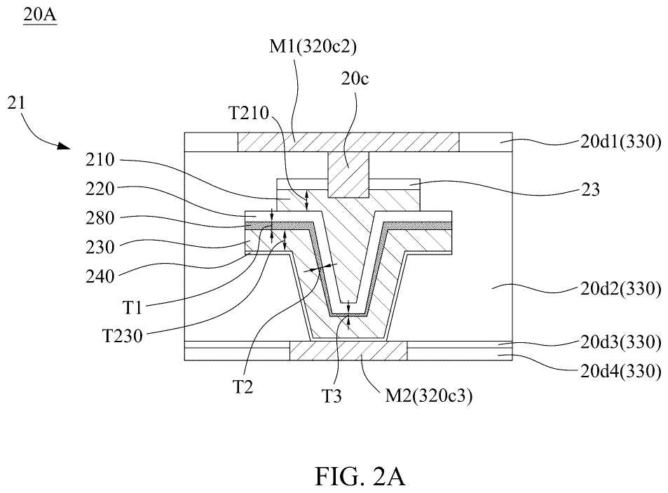

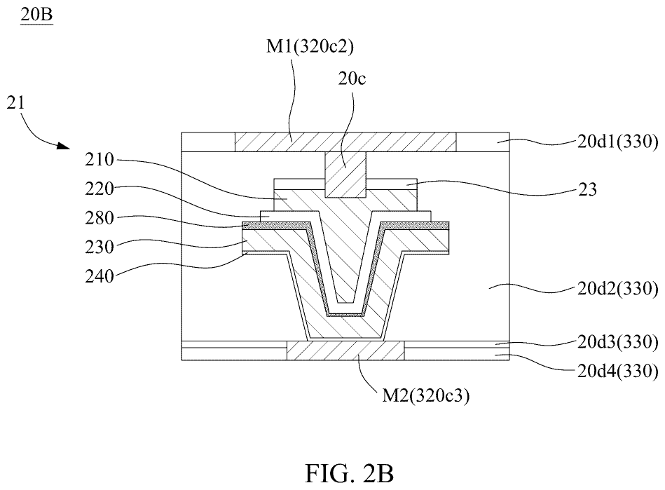

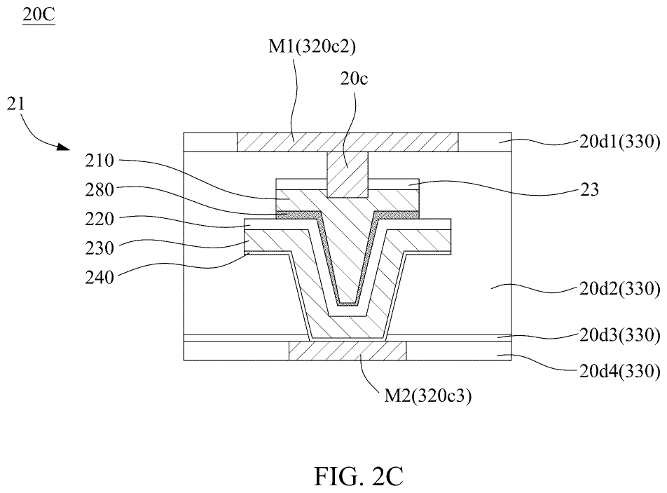

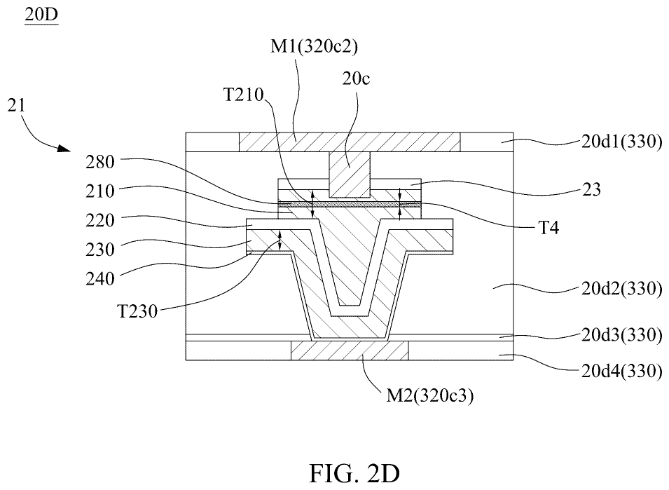

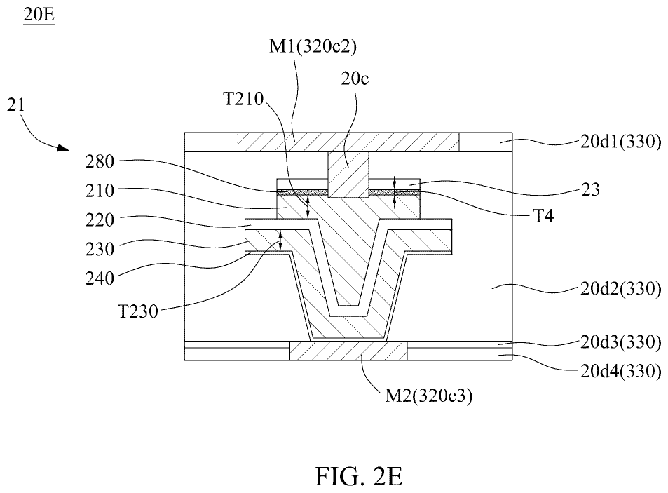

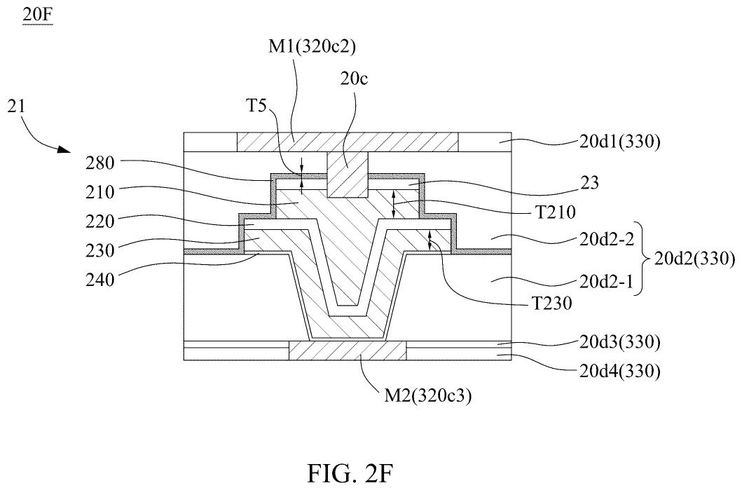

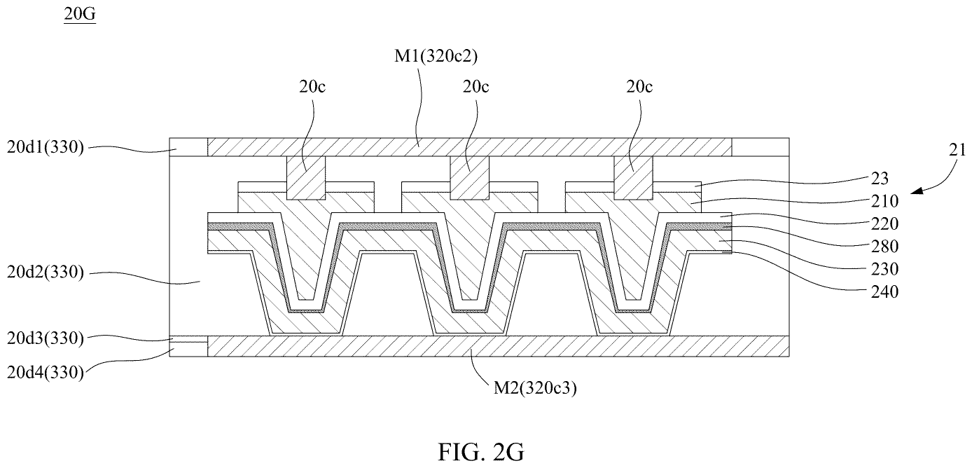

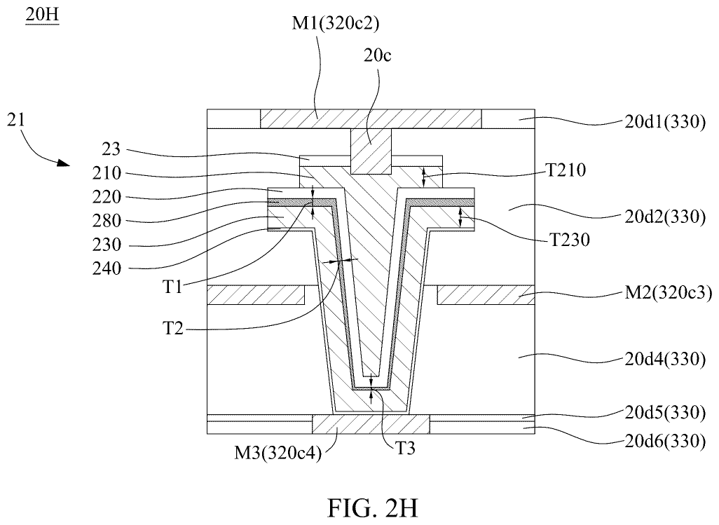

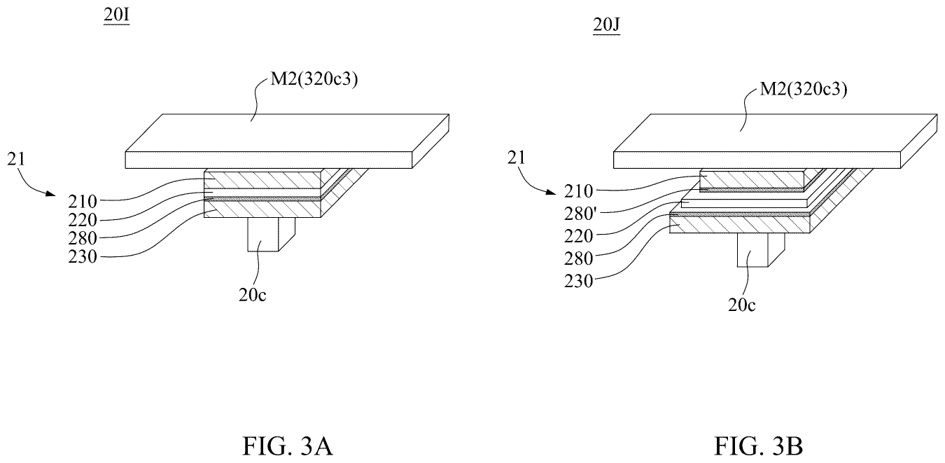

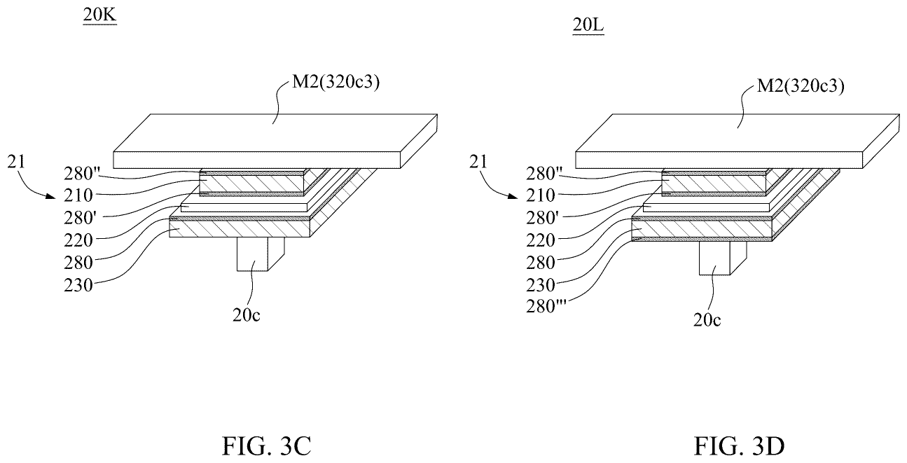

FIG. 2A to FIG. 3D show cross-sections of capacitor structures 20A to 20K according to one or more embodiments of the present disclosure. In some embodiments, the semiconductor device structure 1A or 1B may include any one or more of the following capacitor structures 20A to 20K as illustrated in FIG. 2A to FIG. 3D. In some embodiments, the capacitor structure 20 of the semiconductor device structure 1A or 1B may be replaced by any one or more of the following capacitor structures 20A to 20K as illustrated in FIG. 2A to FIG. 3D.

FIG. 2A is a cross-section of a capacitor structure 20A according to one or more embodiments of the present disclosure.

In some embodiments, the capacitor structure 20A includes a capacitor layer 21, a passivation layer 23, dielectric layers 20d1, 20d2, 20d3, and 20d4, a conductive element 20c, and conductive layers M1 and M2. Referring to FIGS. 1A-1B and FIG. 2A, the dielectric layers 20d1, 20d2, 20d3, and 20d4 may collectively be referred to as a dielectric structure, e.g., the dielectric structure 330 shown in FIGS. 1A-1B, and the conductive layers M1 and M2 may be referred to as the conductive layers 320c2 and 320c3, respectively, shown in FIGS. 1A-1B. In some embodiments, referring to FIGS. 1A-1B and FIG. 2A, the capacitor layer 21 of the capacitor structure 20 is between the semiconductor substrate 100 and the image sensing elements 340.

In some embodiments, the capacitor layer 21 includes conductive layers 210 and 230 (also referred to as “electrodes”), a dielectric layer 220 (also referred to as “an insulator”), and a liner layer 240. In some embodiments, the dielectric layer 220 is between the conductive layers 210 and 230. In some embodiments, the liner layer 240 is disposed under the conductive layer 230 (or the electrode). In some embodiments, the liner layer 240 is between the conductive layer 230 and the dielectric layers 20d2 and 20d3. The liner layer 240 and the conductive layer 230 may collectively form a bottom electrode of the capacitor layer 21 or the capacitor structure 20. The capacitor layer 21 may be referred to as a metal-insulator-metal (MIM) capacitor. The capacitor layer 21 may be referred to as one of the capacitor portions of the capacitor structure 20 illustrated in FIG. 1A and FIG. 1B. In some embodiments, referring to FIG. 1A and FIG. 1B, the capacitor structure 20 may include a plurality of MIM capacitors (e.g., the capacitor layers 21) each corresponding to one of the image sensing elements 340.

In some embodiments, one or more sidewalls of the conductive layer 210 may be substantially aligned with one or more sidewalls of the dielectric layer 220. In some embodiments, one or more sidewalls of the conductive layer 210 may be substantially aligned with one or more sidewalls of the conductive layer 230. In some embodiments, one or more sidewalls of the conductive layer 210 may be substantially aligned with one or more sidewalls of the liner layer 240.

The conductive layers 210 and 230 may include one or more conductive materials, e.g., titanium (Ti), titanium nitride (TiN), tantalum (Ta), tantalum nitride (TaN), copper (Cu), aluminum-copper alloy (AlCu), or other suitable electrode materials. In some embodiments, the Young's modulus of the conductive layers 210 and 230 is independently equal to or less than about 200 GPa, e.g., from about 1 GPa to about 200 GPa. The dielectric layer 220 may be or include one or more high-k dielectric materials, e.g., HfO₂, Ta₂O₅, ZrO₂, Al₂O₃, TiO₂, Y₂O₃, or other suitable high-k dielectric materials. The dielectric layer 220 may be or include a high-k dielectric structure formed of stacked layers ZrO₂/AL₂O₃/ZrO₂ (ZAZ). ZAZ may have the advantageous feature of having a low equivalent oxide thickness, and hence the capacitance value of the resulting capacitor structure 20 is high. In some embodiments, the Young's modulus of the dielectric layer 220 is equal to or less than about 500 GPa, e.g., from about 50 GPa to about 500 GPa. The liner layer 240 may be or include a material layer that blocks the material of the conductive layer 230 (or the electrode) from migrating to surrounding structure. The liner layer 240 may be or include, for example, Ti, Ta, TiN, TaN, or a barrier material for the conductive layer 230. In some embodiments, the Young's modulus of the liner layer 240 is equal to or less than about 200 GPa, e.g., from about 1 GPa to about 200 GPa.

In some embodiments, the passivation layer 23 is over the conductive layer 210. In some embodiments, a sidewall of the passivation layer 23 is substantially aligned with a sidewall of the capacitor layer 21. The passivation layer 23 may include silicon oxynitride. In some embodiments, the Young's modulus of the passivation layer 23 is equal to or less than about 500 GPa, e.g., from about 50 GPa to about 500 GPa.

In some embodiments, the dielectric layer 20d1 is over the dielectric layer 20d2, the dielectric layer 20d2 is over the dielectric layer 20d3, and the dielectric layer 20d3 is over the dielectric layer 20d4. In some embodiments, the dielectric layer 20d1 encapsulates the conductive layer M1. In some embodiments, the dielectric layer 20d2 encapsulates the capacitor layer 21, the passivation layer 23, and the conductive element 20c. The dielectric layers 20d1, 20d2, 20d3, and 20d4 may be or include, for example, silicon dioxide, silicon oxynitride, a low-κ dielectric, silicon carbide, silicon nitride, some other dielectric, or any combination of the foregoing. The dielectric layers 20d1, 20d2, 20d3, and 20d4 may include the same or different dielectric materials. The dielectric layers 20d1, 20d2, and 20d4 may include silicon oxide, and the dielectric layer 20d3 may include silicon carbide. In some embodiments, the Young's modulus of the dielectric layers 20d1, 20d2, 20d3, and 20d4 is independently equal to or less than about 500 GPa, e.g., from about 50 GPa to about 500 GPa.

The conductive layer M1 (also referred to as the conductive layer 320c2 shown in FIG. 1A and FIG. 1B) may be over and electrically connected to the conductive element 20c. The dielectric layer 20d1 (or the dielectric structure 330 shown in FIG. 1A and FIG. 1B) may encapsulate the conductive layer M1. The capacitor layer 21 (or the conductive layer 210) may be electrically connected to the conductive layer M1 through the conductive element 20c. The conductive layer M1 may be or include a metal layer, and the conductive element 20c may be or include a conductive via or a conductive pillar. The metal layer, the conductive via, and the conductive pillar may independently be formed of or include, such as, gold (Au), silver (Ag), aluminum (Al), nickel (Ni), palladium (Pd), copper (Cu) or alloys thereof. In some embodiments, the Young's modulus of the conductive layer M1 is equal to or less than about 200 GPa, e.g., from about 1 GPa to about 200 GPa.

The conductive layer M2 (also referred to as the conductive layer 320c3 shown in FIG. 1A and FIG. 1B) may be disposed on the dielectric layer 20d3. The conductive layer M2 may be electrically connected to the capacitor layer 21. The conductive layer M2 may be or include a metal layer, and the metal layer may be formed of or include, such as, Au, Ag, Al, Ni, Pd, Cu or alloys thereof. In some embodiments, the Young's modulus of the conductive layer M2 is equal to or less than about 200 GPa, e.g., from about 1 GPa to about 200 GPa.

In some embodiments, the reinforcing layer 280 is between the dielectric layer 220 and at least one of the conductive layer 210 and the conductive layer 230. In some embodiments, the reinforcing layer 280 is between the dielectric layer 220 and the conductive layer 230. In some embodiments, the reinforcing layer 280 contacts at least one of the conductive layer 210, the dielectric layer 220, and the conductive layer 230.

In some embodiments, a Young's modulus of the reinforcing layer 280 is greater than a Young's modulus of the conductive layer 210 and a Young's modulus of the conductive layer 230. In some embodiments, a Young's modulus of the reinforcing layer 280 is greater than a Young's modulus of the dielectric layer 220. In some embodiments, the reinforcing layer 280 includes TiC—TiN, AlN, Mo, W, WC, or other suitable high modulus materials. In some embodiments, the reinforcing layer 280 contacts the dielectric layer 220 formed of a high-k material and is free of a dielectric material.

In some embodiments, sidewalls of the dielectric layer 220, the conductive layer 230, the liner layer 240, and the reinforcing layer 280 are substantially aligned. In some embodiments, the dielectric layer 220 is partially exposed by the conductive layer 210.

In some embodiments, the reinforcing layer 280 includes a portion over an upper surface of the conductive layer 230 and having a thickness T1, a portion extending over a sidewall of the conductive layer 230 and having a thickness T2, and a portion on a lower surface of the conductive layer 230 and having a thickness T3. In some embodiments, the thickness T1 is greater than the thickness T2, and the thickness T2 is greater than the thickness T3. In some embodiments, the thickness T2 decreases in a direction from the upper surface toward the lower surface of the conductive layer 230.

In some embodiments, a thickness of the reinforcing layer 280 is about 8% to about 50% of a thickness T210 of the conductive layer 210 and a thickness T230 of the conductive layer 230. In some embodiments, the thickness T1 of the reinforcing layer 180 is about 15% to about 30, the thickness T230 of the conductive layer 230. In some embodiments, the thickness T2 of the reinforcing layer 180 is about 10% to about 30% the thickness T230 of the conductive layer 230. In some embodiments, the thickness T3 of the reinforcing layer 180 is about 8% to about 15% the thickness T230 of the conductive layer 230.

The capacitor structure 20 may be or include a 3D MIM capacitor, and the layers (e.g., the conductive layers 210 and 230 and the dielectric layer 220) of the capacitor structure 20 have non-planar profiles or shapes, which may cause different regions of these layers to experience varying levels of stress. According to some embodiments of the present disclosure, the reinforcing layer having a relatively high Young's modulus is embedded in the capacitor structure 20 and between the electrode (e.g., the conductive layer 230) and insulator (e.g., the dielectric layer 220) of the capacitor layer 21. Therefore, the reinforcing layer, with its higher rigidity, can support the layers of the capacitor structure 20 to prevent deformation caused by the different regions being subjected to varying stresses. As a result, the rigidity of the capacitor structure 20 is increased, and warpage of the semiconductor device package can be reduced.

FIG. 2B is a cross-section of a capacitor structure 20B according to one or more embodiments of the present disclosure. The capacitor structure 20B is similar to the capacitor structure 20A in many aspects, and thus descriptions of these aspects are not repeated for brevity.

In some embodiments, the reinforcing layer 280 is between the dielectric layer 220 and the conductive layer 230. In some embodiments, the reinforcing layer 280 contacts at least one of the conductive layer 210, the dielectric layer 220, and the conductive layer 230. In some embodiments, sidewalls of the conductive layer 230, the liner layer 240, and the reinforcing layer 280 are substantially aligned. In some embodiments, the reinforcing layer 280 is partially exposed by the dielectric layer 220.

FIG. 2C is a cross-section of a capacitor structure 2C according to one or more embodiments of the present disclosure. The capacitor structure 20C is similar to the capacitor structure 20A in many aspects, and thus descriptions of these aspects are not repeated for brevity.

In some embodiments, the reinforcing layer 280 is between the dielectric layer 220 and the conductive layer 210. In some embodiments, the reinforcing layer 280 contacts at least one of the conductive layer 210, the dielectric layer 220, and the conductive layer 230. In some embodiments, sidewalls of the conductive layer 210 and the reinforcing layer 280 are substantially aligned. In some embodiments, the dielectric layer 220 is partially exposed by the reinforcing layer 280.

FIG. 2D is a cross-section of a capacitor structure 20D according to one or more embodiments of the present disclosure. The capacitor structure 20D is similar to the capacitor structure 20A in many aspects, and thus descriptions of these aspects are not repeated for brevity.

The reinforcing layer 280 may be embedded in at least one of the conductive layers 210 and 230. In some embodiments, the reinforcing layer 280 is embedded in at least one of the conductive layers 210 and 230. In some embodiments, sidewalls of the conductive layer 210 and the reinforcing layer 280 are substantially aligned. In some embodiments, the reinforcing layer 280 is formed or disposed over an upper surface of the conductive layer 210 and having a substantially planar profile. In some embodiments, the reinforcing layer 180 has a thickness T4 that is about 8% to about 15% the thickness T230 of the conductive layer 230.

FIG. 2E is a cross-section of a capacitor structure 20E according to one or more embodiments of the present disclosure. The capacitor structure 20E is similar to the capacitor structure 20A in many aspects, and thus descriptions of these aspects are not repeated for brevity.

In some embodiments, the reinforcing layer 280 is between and contacting the passivation layer 23 and the conductive layer 210. In some embodiments, the conductive element 20c penetrates through the reinforcing layer 280 to contact the conductive layer 210.

FIG. 2F is a cross-section of a capacitor structure 20F according to one or more embodiments of the present disclosure. The capacitor structure 20F is similar to the capacitor structure 20A in many aspects, and thus descriptions of these aspects are not repeated for brevity.

In some embodiments, the reinforcing layer 280 contacts the conductive layer 210, the dielectric layer 220, the conductive layer 230, the liner layer 240, and the passivation layer 23. In some embodiments, the dielectric layer 20d2 includes dielectric layers 20d2-1 and 20d2-d separated from each other by the reinforcing layer 280.

In some embodiments, interconnect layers (e.g., the conductive layers 320c1 to 320c5) of the RDL 320 are at different elevations, and the reinforcing layer 280, the conductive layers 210 and 230, and the dielectric layer 220 are between at least two of the interconnect layers of the RDL 320. In some embodiments, the reinforcing layer 280 is conformally over an outer edge of a stacked structure including the conductive layers 210 and 230 and the dielectric layer 220.

FIG. 2G is a cross-section of a capacitor structure 20G according to one or more embodiments of the present disclosure. The capacitor structure 20G is similar to the capacitor structure 20A in many aspects, and thus descriptions of these aspects are not repeated for brevity.

In some embodiments, the dielectric layer 20d2 defines three trenches, and the conductive layer 230 includes three curved portions disposed in the three trenches. In some embodiments, three conductive layers 210 are formed over the three trenches respectively, and three conductive elements 20c are electrically connected to the three conductive layers 210, respectively.

FIG. 2H is a cross-section of a capacitor structure 20H according to one or more embodiments of the present disclosure. The capacitor structure 20H is similar to the capacitor structure 20A in many aspects, and thus descriptions of these aspects are not repeated for brevity.

In some embodiments, the RDL 320 includes at least three interconnect layers (e.g., the conductive layers 320c2, 320c3, 320c4 or the conductive layers M1, M2, and M3) at different elevations, and the reinforcing layer 280, the conductive layers 210 and 230, and the dielectric layer 220 are between at least two of the interconnect layers (e.g., the conductive layers 320c2, 320c3, 320c4 or the conductive layers M1, M2, and M3) of the RDL 320. In some embodiments, the reinforcing layer 280, the conductive layers 210 and 230, and the dielectric layer 220 are between the conductive layer M1 and the conductive layer M3 and passing through an opening defined by the conductive layer M2.

In some embodiments, the thickness T1 of the reinforcing layer 180 is about 30% to about 50% the thickness T230 of the conductive layer 230. In some embodiments, the thickness T2 of the reinforcing layer 180 is about 10% to about 50% the thickness T230 of the conductive layer 230. In some embodiments, the thickness T3 of the reinforcing layer 180 is about 8% to about 15% the thickness T230 of the conductive layer 230.

FIG. 3A is a perspective view of a capacitor structure 20I according to one or more embodiments of the present disclosure. In some embodiments, the capacitor structure 20I is or includes a planar metal-insulator-metal (MIM) capacitor.

In some embodiments, the reinforcing layer 280 is between the conductive layer 230 and the dielectric layer 220. In some embodiments, sidewalls of the conductive layers 210 and 230, the dielectric layer 220, and the reinforcing layer 280 are substantially aligned.

FIG. 3B is a perspective view of a capacitor structure 20J according to one or more embodiments of the present disclosure. The capacitor structure 20J is similar to the capacitor structure 20I in many aspects, and thus descriptions of these aspects are not repeated for brevity.

In some embodiments, the capacitor structure 20J further includes a reinforcing layer 280′ between the conductive layer 210 and the dielectric layer 220. In some embodiments, sidewalls of the conductive layer 210 and the reinforcing layer 280′ are substantially aligned. In some embodiments, sidewalls of the conductive layer 230 and the reinforcing layer 280 are substantially aligned. In some embodiments, the reinforcing layer 280 is partially exposed by the dielectric layer 220. In some embodiments, the dielectric layer 220 is partially exposed by the reinforcing layer 280′.

FIG. 3C is a perspective view of a capacitor structure 20K according to one or more embodiments of the present disclosure. The capacitor structure 20K is similar to the capacitor structure 20I in many aspects, and thus descriptions of these aspects are not repeated for brevity.

In some embodiments, the capacitor structure 20J further includes a reinforcing layer 280″ between the conductive layer 320c3 and the conductive layer 210. In some embodiments, sidewalls of the conductive layer 210 and the reinforcing layers 280′ and 280″ are substantially aligned.

FIG. 3D is a perspective view of a capacitor structure 20L according to one or more embodiments of the present disclosure. The capacitor structure 20L is similar to the capacitor structure 20I in many aspects, and thus descriptions of these aspects are not repeated for brevity.

In some embodiments, the capacitor structure 20J further includes a reinforcing layer 280′″ between the conductive element 20c and the conductive layer 230. In some embodiments, sidewalls of the conductive layer 230 and the reinforcing layers 280 and 280′″ are substantially aligned.

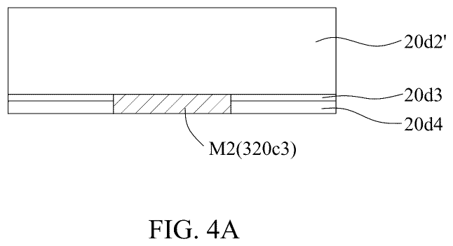

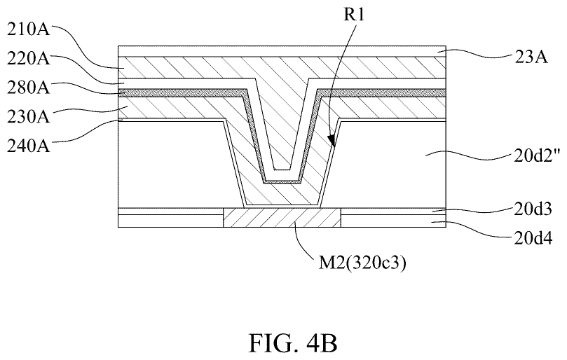

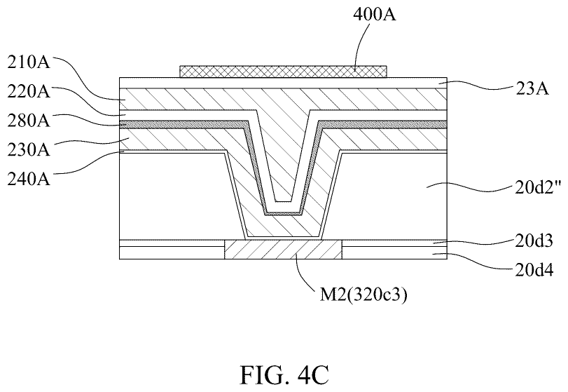

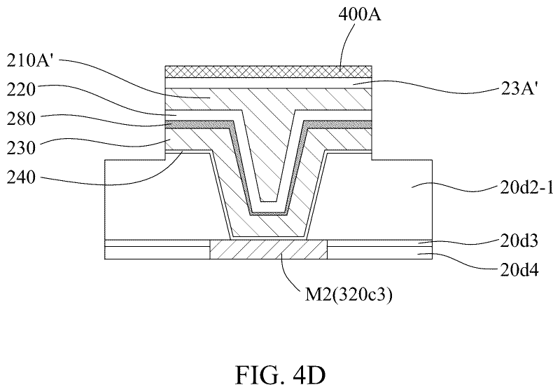

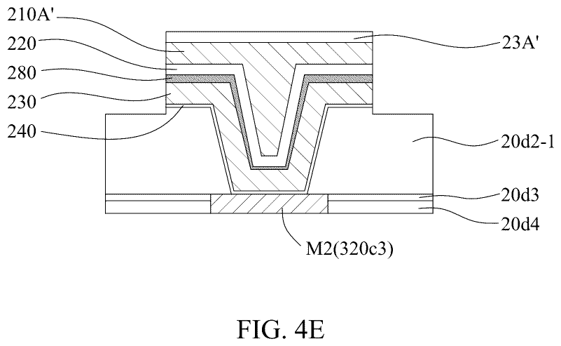

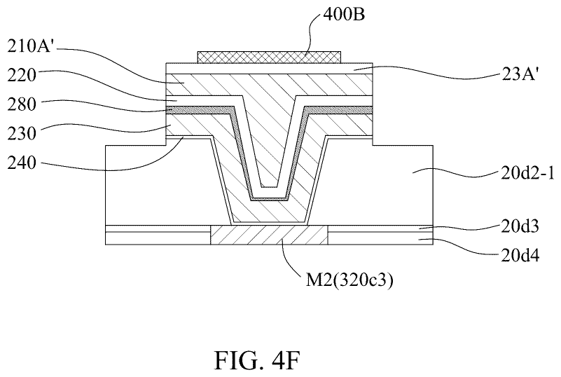

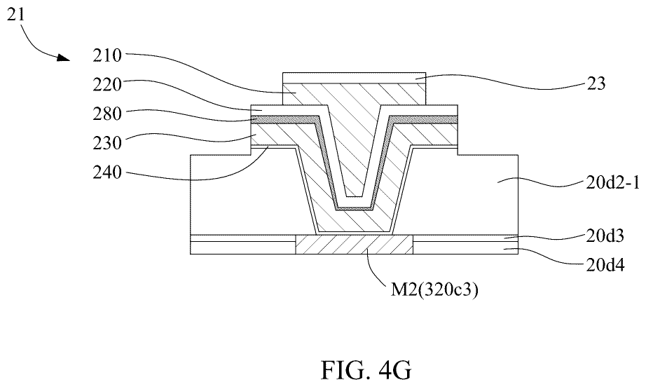

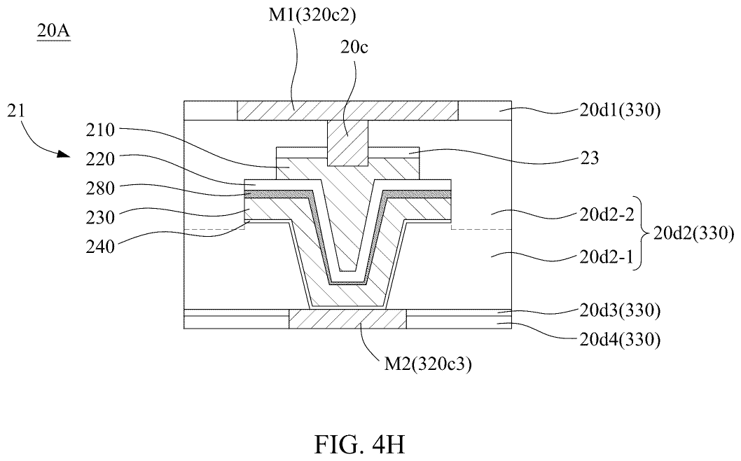

FIGS. 4A to 4H are cross-sections illustrating a method for forming a capacitor structure 20A according to one or more embodiments of the present disclosure. In some embodiments, referring to FIGS. 1A-1B and FIGS. 4A to 4H, a method for forming a semiconductor device package 1A or 1B may be provided.

Referring to FIG. 4A, a conductive layer M4 may be formed within dielectric layers 20d3 and 20d4, and a dielectric layer 20d2 may be formed on the conductive layer M2 and the dielectric layers 20d3 and 20d4.

Referring to FIG. 4B, a portion of the dielectric layer 20d2′ may be removed to form a dielectric layer 20d2″ having a trench R1, a liner layer 240A, a conductive layer 230A, a reinforcing layer 280A a dielectric layer 220A1 and a conductive layer 210A may be formed in the trench R1 and over the dielectric layer 20d2″, and a passivation layer 23A may be formed on the conductive layer 210A. Referring to FIG. 1A and FIG. 4A, the conductive layer 210A may be formed over the semiconductor substrate 100. In some embodiments, the liner layer 240A is formed over dielectric layer 20d2″, the conductive layer 230A is formed over the liner layer 240A, the reinforcing layer 280A is formed over the conductive layer 230A, the dielectric layer 220A is formed over the reinforcing layer 280A, the conductive layer 210A is formed over the dielectric layer 220A, and the passivation layer 23A is formed over the conductive layer 210A.

In some embodiments, the reinforcing layer 280A is formed between the conductive layer 210A and a portion of the dielectric layer 20d2″. In some embodiments, a Young's modulus of the reinforcing layer 280A is greater than a Young's modulus of the conductive layer 210A. In some embodiments, forming the reinforcing layer 280A includes depositing a metal material on the conductive layer 230 by atomic layer deposition (ALD).

Referring to FIG. 4C, a sacrificial pattern 400A may be formed over the passivation layer 23A. In some embodiments, the sacrificial pattern 400A includes a material different from that of the dielectric layer 20d2″. The sacrificial pattern 400A may be or include a mask layer and/or a photoresist layer. The sacrificial pattern 400A may be or include silicon nitride. The sacrificial pattern 400A serves to define a pattern, a coverage, a shape, or a range of the underneath layers to be formed.

Referring to FIG. 4D, the liner layer 240A, the conductive layers 210A and 230A, the reinforcing layer 280A, the dielectric layer 220A, the passivation layer 23A and the dielectric layer 20d2″ may be partially removed by etching to form the liner layer 240, the conductive layer 230, the reinforcing layer 280, the dielectric layer 220, the conductive layer 210A′, the passivation layer 23A, and the dielectric layer 20d2-1. The sidewalls of the liner layer 240, the conductive layer 230, the reinforcing layer 280, the dielectric layer 220, the conductive layer 210A′, and the passivation layer 23A′ may be exposed and substantially aligned.

Referring to FIG. 4E, the sacrificial pattern 400A may be removed.

Referring to FIG. 4F, a sacrificial pattern 400B may be formed over the passivation layer 23A′. In some embodiments, the sacrificial pattern 400B includes a material different from that of the dielectric layers 20d2-1. The sacrificial pattern 400B may be or include a mask layer and/or a photoresist layer. The sacrificial pattern 400A may be or include silicon nitride. The sacrificial pattern 400A serves to define a pattern, a coverage, a shape, or a range of the passivation layer 23 and the conductive layer 210 to be formed.

Referring to FIG. 4G, the passivation layer 23A′ and the conductive layer 210′ may be partially removed by etching to form the passivation layer 23 and the conductive layer 210, so as to form the capacitor layer 21. The sidewalls of the passivation layer 23 and the conductive layer 210 may be exposed and substantially aligned.

Referring to FIG. 4H, a dielectric layer 20d2-2 may be formed over the capacitor layer 21 and the dielectric layer 20d2-1. The dielectric layer 20d2-1 and the dielectric layer 20d2-2 may collectively form a dielectric layer 20d2. The dielectric layer 20d2 may be referred to as a portion of the dielectric structure 330 shown in FIG. 1A and FIG. 1B. In some embodiments, the dielectric layer 20d2 (of the dielectric structure 330) encapsulates the conductive layers 210 and 230 and the dielectric layer 220.

Still referring to FIG. 4H, a conductive element 20c may be formed to penetrate the dielectric layer 20d2 and the passivation layer 23 to contact and electrically connect to the capacitor layer 21, a conductive layer M2 may be formed on and electrically connected to the conductive element 20c, and a dielectric layer 20d1 may be formed over the dielectric layer 20d2 and encapsulating the conductive layer M2. As such, the capacitor structure 20A may be formed.

In some embodiments, referring to FIGS. 1A-1B and FIG. 4H, a die 10 including a semiconductor substrate 100, a circuit layer 110, an RDL 120, and a dielectric structure 130 may be provided. In some embodiments, the circuit layer 110 is formed on and partially within the semiconductor substrate 100, and the RDL 120 including conductive layers 120c and 120c1 and connection elements 120v are formed over the semiconductor substrate 100. In some embodiments, the dielectric structure 130 may be formed to encapsulate the circuit layer 110 and the RDL 120.

In some embodiments, referring to FIGS. 1A-1B and FIG. 4H, a die 30 including a semiconductor substrate 300, a circuit layer 310, a RDL 320, a dielectric structure 330, image sensing elements 340, isolation structures 350, a grid structure 360, a dielectric liner 370, and the capacitor structure 20 (or the capacitor layers 21) may be provided. In some embodiments, the image sensing elements 340, the isolation structures 350, and the dielectric liner 370 are formed in the semiconductor substrate 300. In some embodiments, the circuit layer 310 is formed on and partially within the semiconductor substrate 300. In some embodiments, the RDL 320 including conductive layers 320c1, 320c2, 320c3, 320c4, and 320c5 and connection elements 320v and 320p are formed over the semiconductor substrate 300. In some embodiments, the capacitor structure 20 (or the capacitor layers 21) may be formed between the conductive layer 320c2 (or the conductive layer M1 shown in FIG. 4H) and the conductive layer 320c3 (or the conductive layer M2 shown in FIG. 4H), and a dielectric structure 330 may be formed to encapsulate the RDL 320 and the capacitor structure 20.

In some embodiments, referring to FIGS. 1A-1B and FIG. 4H, the die 10 is connected to or bonded to the die 30. In some embodiments, the image sensing elements 340 may be formed over the capacitor layer 21. As such, semiconductor device package 1A or 1B including the capacitor structure 20A may be formed.

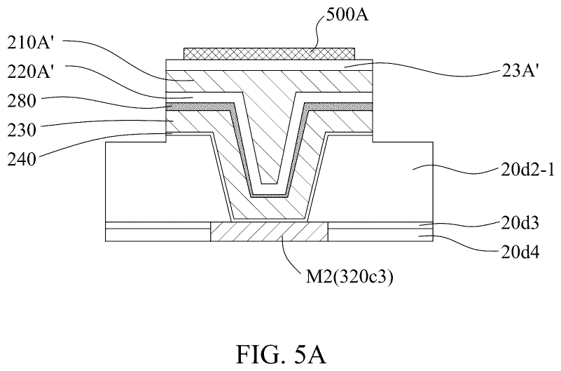

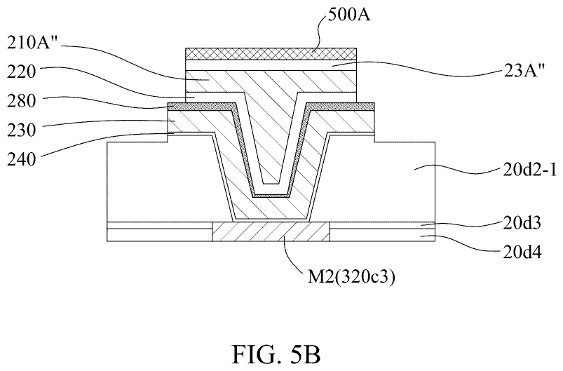

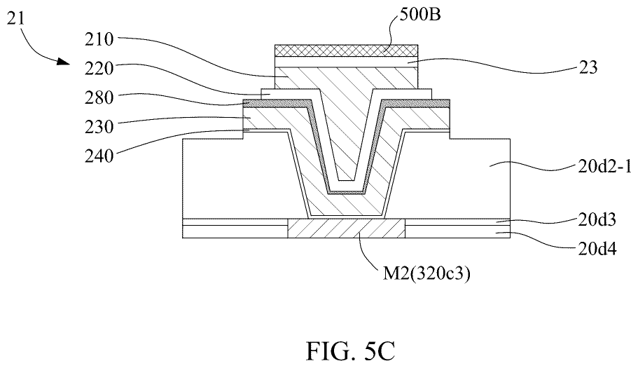

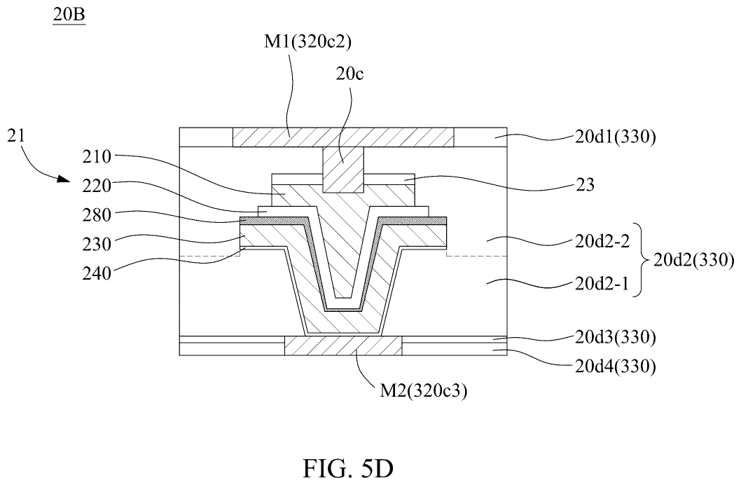

FIGS. 5A to 5D are cross-sections illustrating a method for forming a capacitor structure 20B according to one or more embodiments of the present disclosure. In some embodiments, referring to FIGS. 1A-1B and FIGS. 5A to 5D, a method for forming a semiconductor device package 1A or 1B may be provided.

Referring to FIG. 5A, operations similar to those illustrated in FIGS. 4A-4E may be performed to form the liner layer 240, the conductive layer 230, the reinforcing layer 280, the dielectric layer 220A′, the conductive layer 210A′, the passivation layer 23A′, and the dielectric layer 20d2-1 illustrated in FIG. 5A, and a sacrificial pattern 500A may be formed over the passivation layer 23A′. In some embodiments, the sacrificial pattern 500A includes a material different from that of the dielectric layers 20d2-1. The sacrificial pattern 500A may be or include a mask layer and/or a photoresist layer. The sacrificial pattern 500A may be or include silicon nitride. The sacrificial pattern 500A serves to define a pattern, a coverage, a shape, or a range of the underneath layers to be formed.

Referring to FIG. 5B, the dielectric layer 220A′, the passivation layer 23A′, and the conductive layer 210′ may be partially removed by etching to form the dielectric layer 220, the passivation layer 23A″, and the conductive layer 210A″, and to expose a portion of the reinforcing layer 280 by the dielectric layer 220.

Referring to FIG. 5C, the sacrificial pattern 500A may be removed, and a sacrificial pattern 500B may be formed over the passivation layer 23A″. In some embodiments, the sacrificial pattern 500B includes a material different from that of the dielectric layers 20d2-1, the liner layer 240, the conductive layer 230, the reinforcing layer 280, and the dielectric layer 220. The sacrificial pattern 500B may be or include a mask layer and/or a photoresist layer. The sacrificial pattern 500B may be or include silicon nitride. The sacrificial pattern 500B serves to define a pattern, a coverage, a shape, or a range of the passivation layer 23 and the conductive layer 210 to be formed, so as to form the capacitor layer 21.

Referring to FIG. 5D, the sacrificial pattern 500B may be removed, and operation similar to those illustrated in FIG. 4H may be performed to form the dielectric layer 20d2, the conductive element 20c, the conductive layer M1, and the dielectric layer 20d1. As such, the capacitor structure 20B may be formed.

In some embodiments, referring to FIGS. 1A-1B and FIG. 5D, similar to those described above, the die 10 is connected to or bonded to the die 30. As such, semiconductor device package 1A or 1B including the capacitor structure 20B may be formed.

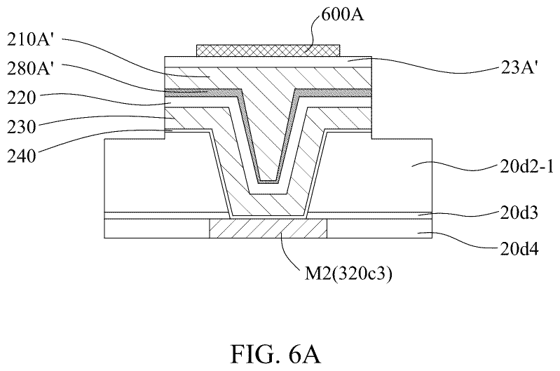

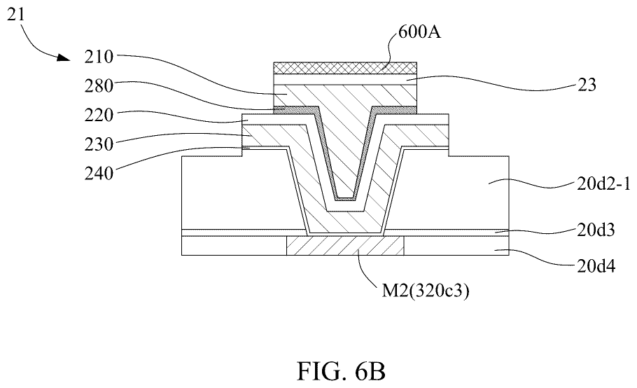

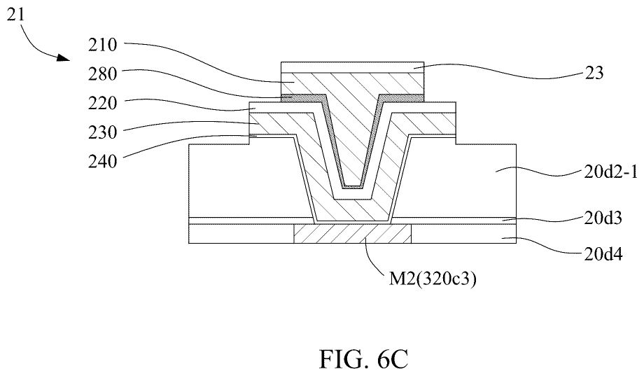

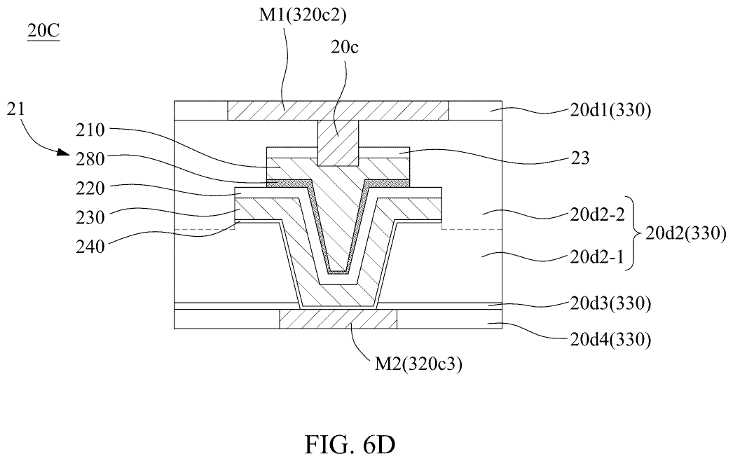

FIGS. 6A to 6D are cross-sections illustrating a method for forming a capacitor structure 20C according to one or more embodiments of the present disclosure. In some embodiments, referring to FIGS. 1A-1B and FIGS. 6A to 6D, a method for forming a semiconductor device package 1A or 1B may be provided.

Referring to FIG. 6A, operations similar to those illustrated in FIGS. 4A-4E may be performed to form the liner layer 240, the conductive layer 230, the dielectric layer 220A, the reinforcing layer 280′, the conductive layer 210A′, the passivation layer 23A′, and the dielectric layer 20d2-1 illustrated in FIG. 6A, and a sacrificial pattern 600A may be formed over the passivation layer 23A′. In some embodiments, the sacrificial pattern 600A includes a material different from that of the dielectric layers 20d2-1. The sacrificial pattern 600A may be or include a mask layer and/or a photoresist layer. The sacrificial pattern 600A may be or include silicon nitride. The sacrificial pattern 600A serves to define a pattern, a coverage, a shape, or a range of the underneath layers to be formed.

Referring to FIG. 6B, the reinforcing layer 280′, the passivation layer 23A′, and the conductive layer 210′ may be partially removed by etching to form the reinforcing layer 280, the passivation layer 23A, and the conductive layer 210A, and to expose a portion of the dielectric layer 220 by the reinforcing layer 280, so as to form the capacitor layer 21.

Referring to FIG. 6C, the sacrificial pattern 500A may be removed.

Referring to FIG. 6D, operation similar to those illustrated in FIG. 4H may be performed to form the dielectric layer 20d2, the conductive element 20c, the conductive layer M1, and the dielectric layer 20d1. As such, the capacitor structure 20C may be formed.

In some embodiments, referring to FIGS. 1A-1B and FIG. 6D, similar to those described above, the die 10 is connected to or bonded to the die 30. As such, semiconductor device package 1A or 1B including the capacitor structure 20C may be formed.

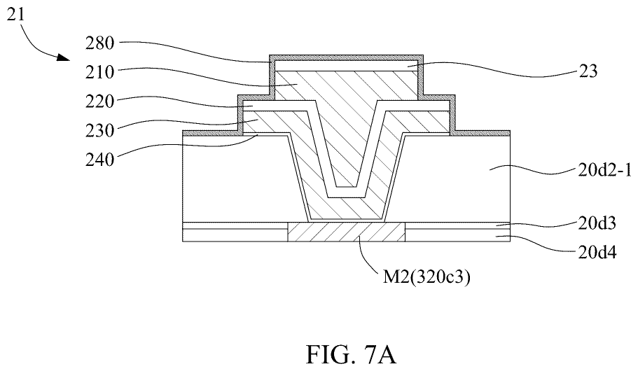

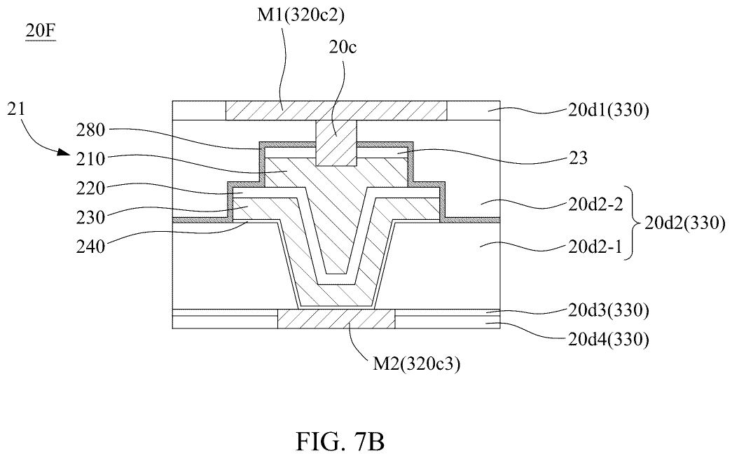

FIGS. 7A to 7B are cross-sections illustrating a method for forming a capacitor structure 20F according to one or more embodiments of the present disclosure.

Referring to FIG. 7A, operations similar to those illustrated in FIGS. 4A-4G may be performed to form the capacitor layer 21 including the liner layer 240, the conductive layers 210 and 230, and the dielectric layer 220, and then a reinforcing layer 280 is formed over the capacitor layer 21. In some embodiments, the reinforcing layer 280 is formed by depositing a dielectric material having a Young's modulus from about 200 GPa to about 1200 GPa by ALD. In some embodiments, the reinforcing layer 280 is conformally formed over an outer edge of a stacked structure including at least the conductive layers 210 and 230 and the dielectric layer 220.

Referring to FIG. 7B, operation similar to those illustrated in FIG. 4H may be performed to form the dielectric layer 20d2, the conductive element 20c, the conductive layer M1, and the dielectric layer 20d1. As such, the capacitor structure 20F may be formed.

In some embodiments, referring to FIGS. 1A-1B and FIG. 7B, similar to those described above, the die 10 is connected to or bonded to the die 30. As such, semiconductor device package 1A or 1B including the capacitor structure 20F may be formed.

Some embodiments of the present disclosure provide a method for forming an image sensor structure. The method includes following operations: forming a first conductive layer over a semiconductor substrate; forming a dielectric layer over the first conductive layer; forming a second conductive layer over the dielectric layer; forming a dielectric structure encapsulating the first conductive layer, the dielectric layer, and the second conductive layer; and forming a reinforcing layer between the first conductive layer and a portion of the dielectric structure, wherein a Young's modulus of the reinforcing layer is greater than a Young's modulus of the first conductive layer.

Some embodiments of the present disclosure provide a method for forming an image sensor structure. The method includes following operations: forming a first electrode over a semiconductor substrate; forming an insulator over the first electrode; forming a second electrode over the insulator; forming a dielectric structure covering the first electrode, the insulator, and the second electrode; and forming a stress-resistant layer contacting the dielectric structure, wherein a Young's modulus of the stress-resistant layer is greater than a Young's modulus of the first electrode and a Young's modulus of the second electrode.

Some embodiments of the present disclosure provide a semiconductor device structure. The semiconductor device structure includes a first conductive layer, a second conductive layer, a dielectric layer, a dielectric structure, and a reinforcing layer. The dielectric layer is between the first conductive layer and the second conductive layer. The dielectric structure encapsulates the first conductive layer, the dielectric layer, and the second conductive layer. The reinforcing layer is between the first conductive layer and a portion of the dielectric structure and contacts the dielectric structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device structure, comprising:
forming a first conductive layer over a semiconductor substrate;
forming a dielectric layer over the first conductive layer;
forming a second conductive layer over the dielectric layer;
forming a dielectric structure encapsulating the first conductive layer, the dielectric layer, and the second conductive layer; and
forming a reinforcing layer between the first conductive layer and a portion of the dielectric structure, wherein a Young's modulus of the reinforcing layer is greater than a Young's modulus of the first conductive layer.

2. The method of claim 1, further comprising:
partially removing the first conductive layer, the dielectric layer, the second conductive layer, and the reinforcing layer by a first etching process to expose and substantially align sidewalls of the first conductive layer, the dielectric layer, the second conductive layer, and the reinforcing layer.

3. The method of claim 2, further comprising:
partially removing the dielectric layer and the second conductive layer by a second etching process to expose a portion of the reinforcing layer by the dielectric layer.

4. The method of claim 2, further comprising:
partially removing the reinforcing layer and the second conductive layer by a second etching process to expose a portion of the dielectric layer by the reinforcing layer.

5. The method of claim 1, wherein forming the reinforcing layer is performed after forming the first conductive layer, the dielectric layer, the second conductive layer, and forming the dielectric structure is performed after forming the reinforcing layer.

6. The method of claim 5, wherein the reinforcing layer is conformally formed over an outer edge of a stacked structure including the first conductive layer, the dielectric layer, the second conductive layer, and the method further comprises forming a conductive element penetrating the reinforcing layer to contact the first conductive layer.

7. A method for forming a semiconductor device structure, comprising:
forming a first electrode over a semiconductor substrate;
forming an insulator over the first electrode;
forming a second electrode over the insulator;
forming a dielectric structure covering the first electrode, the insulator, and the second electrode; and
forming a stress-resistant layer contacting the dielectric structure, wherein a Young's modulus of the stress-resistant layer is greater than a Young's modulus of the first electrode and a Young's modulus of the second electrode.

8. The method of claim 7, wherein the stress-resistant layer further contacts at least one of the first electrode, the insulator, and the second electrode.

9. The method of claim 7, wherein forming the stress-resistant layer comprises depositing a metal material on the first electrode by atomic layer deposition (ALD), the insulator is formed on and contacting the stress-resistant layer, and a Young's modulus of the metal material is greater than a Young's modulus of the insulator.

10. The method of claim 7, wherein forming the stress-resistant layer comprises depositing a metal material on the insulator by ALD, and a Young's modulus of the metal material is greater than a Young's modulus of the insulator.

11. The method of claim 7, wherein forming the stress-resistant layer comprises depositing a dielectric material on at least one of the first electrode and the second electrode by ALD, and a Young's modulus of the dielectric material is from about 200 GPa to about 1200 GPa.

12. The method of claim 11, wherein a thickness of the stress-resistant layer is about 8% to about 50% of a thickness of the first electrode and a thickness of the second electrode.

13. A semiconductor device structure, comprising:
a first conductive layer and a second conductive layer;
a dielectric layer between the first conductive layer and the second conductive layer;
a dielectric structure encapsulating the first conductive layer, the dielectric layer, and the second conductive layer; and
a reinforcing layer between the first conductive layer and a portion of the dielectric structure and contacting the dielectric structure.

14. The semiconductor device structure of claim 13, wherein the reinforcing layer is between the dielectric layer and at least one of the first conductive layer and the second conductive layer.

15. The semiconductor device structure of claim 13, wherein the reinforcing layer is embedded in at least one of the first conductive layer and the second conductive layer.

16. The semiconductor device structure of claim 13, further comprising a passivation layer over the first conductive layer, wherein the reinforcing layer is between and contacting the passivation layer and the first conductive layer.

17. The semiconductor device structure of claim 13, wherein the reinforcing layer further contacts the first conductive layer, the dielectric layer, and the second conductive layer.

18. The semiconductor device structure of claim 13, further comprising a first interconnect layer, a second interconnect layer, and a third interconnect layer at different elevations, wherein the reinforcing layer, the first conductive layer, the dielectric layer, and the second conductive layer are between the first interconnect layer and the third interconnect layer and passing through an opening defined by the second interconnect layer.

19. The semiconductor device structure of claim 13, further comprising a redistribution layer (RDL) electrically connected to the first conductive layer and comprising a plurality of interconnect layers, wherein the reinforcing layer is embedded in the dielectric structure and contacting at least one of the interconnect layers.

20. The semiconductor device structure of claim 13, further comprising a first interconnect layer and a second interconnect layer at different elevations, wherein the reinforcing layer, the first conductive layer, the dielectric layer, and the second conductive layer are between the first interconnect layer and the second interconnect layer, and the reinforcing layer is conformally over an outer edge of a stacked structure including the first conductive layer, the dielectric layer, and the second conductive layer.
